(19) United States
(12) Patent Application Publication
(10) Pub. No.: US 2024/0372042 A1
(43) Pub. Date: Nov. 7, 2024

(54) STACK OF ANTENNA-EFFECT MATERIALS AND OPTOELECTRONIC DEVICE COMPRISING SUCH A STACK

(71) Applicant: ALEDIA, Échirolles (FR)

(72) Inventors: Christophe LINCHENEAU, Moirans (FR); Eleonora GARONI, Seyssinet-Pariset (FR)

(73) Assignee: ALEDIA, Échirolles (FR)

(21) Appl. No.: 18/291,158

(22) PCT Filed: Jul. 18, 2022
(86) PCT No.: PCT/FR2022/051425

§ 371 Date: Jan. 22, 2024

(30) Foreign Application Priority Data
Jul. 22, 2021 (FR) FR2107908

(51) Int. Cl. H01L 33/44; C09K 11/02; C09K 11/06; H01L 27/15

(52) U.S. Cl. CPC H01L 33/44; C09K 11/02; C09K 11/06; H01L 27/15; C09K 2211/1018

(57) ABSTRACT

A stack of antenna-effect materials that includes a superposition of rare-earth layers on chromophores layers. Also, an optoelectronic device the sub-pixels of which may include: a light-conversion module including a conversion pad and/or a filter. the conversion pad and/or the filter including the stack of antenna-effect materials.

The invention concerns a stack of antenna-effect materials and an optoelectronic device comprising such a stack. More particularly, the optoelectronic device includes a plurality of pixels which each comprise a plurality of sub-pixels, said sub-pixels comprising a light conversion module and/or a filter comprising such a stack.

By “optoelectronic device” is meant in the context of the present invention a device adapted to perform the conversion of an electrical signal into electromagnetic radiation to be emitted (in particular light).

There are optoelectronic devices including a light emitter matrix, preferably light emitting diodes (hereinafter abbreviated “LED”) having an emission surface through which the light radiation emitted by the LEDs is transmitted. Such optoelectronic devices are used in the construction of display screens or image projection systems, in which the matrix of LEDs defines a matrix of “image elements” (also called “pixels”) each of which emits light, so that the image on the screen may be controlled by individually activating or deactivating each pixel. More specifically, the LEDs have the form of a stack of semiconductor layers. The light is emitted when an electric current flows through the stack.

Each pixel comprises several sub-pixels. Each sub-pixel itself comprises at least one light emitter, preferably a LED. A sub-pixel may contain a plurality of LEDs. Each sub-pixel is configured to emit a specific color, so that the color emitted by the pixel may be modified by controlling the sub-pixels to be activated on or by modifying the electric current applied to each LED in order to modify the relative emission intensity of each sub-pixel. Each sub-pixel itself comprises at least one LED. A sub-pixel may contain a plurality of LEDs.

Even if it is possible to envisage LEDs of any color, it is advantageous to use LEDs capable of emitting light radiation corresponding to a blue or ultraviolet color. Indeed, these colors are the easiest to manufacture and they release the most energy for the manufacture of other colors in association with phosphor-type color conversion pads as detailed below. In this way, the other colors such as red or green may easily be obtained.

This is why, so that the optoelectronic device is capable of representing multicolor images, it is known to have pixels for which each sub-pixel is capable of emitting different colors. To do this, each sub-pixel may comprise a light conversion module which comprises at least one conversion pad capable of emitting radiation of different colors from the original color of the LED that the sub-pixel comprises. More precisely, the conversion pads comprise a photoluminescent (or in other words phosphor) material. We also speak of photoluminescent pads. Each conversion pad is designed so as to absorb at least part of the light, for example of blue color, emanating from the LED that the sub-pixel comprises and to emit in response a light of different color, for example green or red.

The conversion pads generally comprise a binding matrix of an appropriate resin, for example a photo-or heat-sensitive resin, within which are incorporated nano-sized crystals of a semiconductor material or in other words quantum dots. By way of example, they may be cadmium selenide nanocrystals whose average size is in the range of 3.6 nm which are suitable for converting blue light into red light or else cadmium selenide nanocrystals whose average size is in the range of 1.3 nm which are suitable for converting the blue light into green light.

However, the use of quantum dots as constituents of the conversion pads poses the following difficulties:
toxicity problems (especially in the case of cadmium, selenium, tellurium or indium);
process problems due to the fact that their implementation within optoelectronic devices is complex. Indeed, during the manufacture of the conversion pads, the photolithography technique is generally used to deposit around the LED (which is advantageously in the form of a nano-wire) a mixture containing the quantum dots and the photo-or heat-sensitive resin. However, this mixture is complex to deposit with the photolithography technique.
reliability problems: the quantum dots, in particular those comprising cadmium or indium, are sensitive to the surrounding environment, in particular to oxidation due to external agents such as water, air or free radicals resulting from polymerization reactions of the photo-or heat-sensitive resin. Moreover, their stability may be low (in the range of a few hours) when they are subjected to a flow of heat and/or light, which is the case in the optoelectronic devices.

Thus, the use of quantum dots as constituents of conversion pads is not satisfactory. This is why we are looking for other constituents that could replace the quantum dots.

The rare earths are a group of metals with properties similar to each other which comprises scandium and yttrium and the 15 lanthanides ranging from lanthanum to lutetium. Lanthanides are generally referred to by the collective chemical symbol “Ln”. They all form trivalent cations Ln³⁺.

The rare earths, and in particular the lanthanides, have very interesting and unique optical properties: their emission bands are precise and narrow and range from visible to near infrared (above 1200 nm). They are indeed much narrower than those of quantum dots. Finally, the position of these emission bands does not vary depending on the environment (for example temperature). Each rare earth thus has distinct spectral properties. Furthermore, with the exception of La(III) and Lu(III) ions, lanthanide ions are luminescent. This is why rare earths are often used for their luminescence properties.

In addition, the rare earths have the advantage of being inert materials. This is why, in view of all these properties, they seem to be materials of choice as materials used in the composition of the conversion pads.

However, the molar extinction coefficients of rare earths and in particular of Ln (III) ions are low. This is why it is necessary to use intense light sources (such as laser) to be able to excite them directly.

It is also known to indirectly excite rare earths via an “antenna effect”. To do this, the rare earth is associated with a chromophore which has a high molar extinction coefficient and which thus acts as a photon collector. Indeed, a chromophore subjected to a light excitation will absorb the light energy and populate its excited states. Then, an energy transfer takes place towards the rare earth thus allowing the effective population of its excited states. Finally, the excited states of the rare earth are relaxed by a radiative process, leading to the emission of light. Thanks to the chromophore, the rare earth may thus re-emit light.

This sequence of energy transfers implies an adequate energy difference between the absorption of photons by the chromophore (in other words “the antenna”) and the emission of photons during the relaxation of the rare earth. This results in a large Stokes shift.

The efficiency of the energy transfer depends on the distance between the chromophore and the rare earth. Thus, the closer the chromophore is to the rare earth, the more efficient the energy transfer will be and the greater the luminescence emission of the rare earth will be. The efficiency of the energy transfer also depends on the overlap between the absorption spectra of the rare earth and the emission spectra of the chromophore.

This is why it is known in the state of the art to use compounds which form complexes with the rare earths and which in addition are iono-covalently linked to at least one chromophore. For example, in patent FR 3 061 714 B1, these compounds are dendrimers and in patent FR 3 061 713 B1, these compounds are triethylenetetramine-N,N,N′, N″, N″, N″′-hexaacetic acid derivatives. These compounds make it possible to bring the rare earth closer to the chromophore (in other words the antenna) so that the antenna effect may occur and thus the rare earth re-emits light. The known applications of such systems are in particular the fields of medical imaging and photovoltaics.

The inventors of the present invention have developed another way of bringing the rare earth closer to the chromophore to obtain the antenna effect, and this by avoiding compounds forming a complex with the rare earth. Indeed, the inventors have discovered quite surprisingly that this antenna effect could perfectly be obtained with a stack of a layer of rare earth on a layer of chromophore or with a stack of a superposition of layers of earth rare on layers of chromophore.

This is why the present invention also relates to a stack of antenna-effect materials which is characterized in that it comprises at least one layer of rare earth on at least one layer of a chromophore, said rare earth being different from lutetium and lanthanum. Thus, preferably, said stack is configured so that an energy transfer takes place between the materials forming said layers, when said stack is subjected to a light excitation. The technical characteristics of this stack are described in more detail below.

The present invention also relates to an optoelectronic device comprising at least one light emitter and it is characterized in that it further comprises at least one stack of antenna-effect materials according to the invention.

This stack may find various applications, among which mention may be made of the conversion pads of the light conversion modules and the filters of the optoelectronic devices.

This is why the present invention also relates to an optoelectronic device comprising a plurality of pixels which each comprise a plurality of sub-pixels, each sub-pixel is configured to emit a specific color and comprises said at least one light emitter emitting a light radiation of a given color, at least one of said sub-pixels comprises:
at least one light conversion module disposed on said at least one light emitter that said at least one sub-pixel comprises, said light conversion module comprising at least one conversion pad capable of emitting a radiation of a color different from that of the light radiation emitted by said at least one light emitter,
   and/or
at least one filter disposed on said light conversion module and which is capable of emitting radiation of the same color as that of the light radiation emitted by the light conversion module and/or capable of blocking any radiation of a color different from that of the light radiation emitted by the light conversion module or, when said at least one sub-pixel does not have said light conversion module, said filter is disposed on the at least one light emitter that said at least one sub-pixel comprises and is capable of emitting a radiation of the same color as that of the light radiation emitted by the at least one light emitter and/or said filter is capable of blocking any radiation of a color different from that of the light radiation emitted by the at least a light emitter, said optoelectronic device is characterized in that said at least one conversion pad and/or said at least one filter comprises a stack of antenna-effect materials according to the invention. Preferably, said stack is integrated within a photo-or heat-sensitive resin.

In other words, the stack may be:
a layer of rare earth on a layer of chromophore,
   or
a superposition of layers of rare earth on layers of chromophore or in other words an alternation of layers of rare earth and of layers of chromophore.

Thus, the optoelectronic device according to the invention has the following advantages:
its conversion pads and/or its filters which comprise a stack of at least one layer of rare earth on at least one layer of chromophore are non-toxic, reliable over time and therefore do not risk degrading, because rare earths (unlike quantum dots) are non-toxic, perfectly stable over time (at least a few years), chemically inert and therefore not affected by the environment (notably heat and light) and not sensitive to oxidation;
the configuration in the form of a stack of layers of rare earth on layers of chromophore enables the antenna effect to be obtained and provides its conversion pads and/or its filters with good quantum efficiency.

The optoelectronic device according to the invention may have the following variants:
at least one sub-pixel includes at least one light conversion module which comprises at least one conversion pad comprising a stack of antenna-effect materials according to the invention and no filter is disposed on said light conversion module;
at least one sub-pixel includes at least one light conversion module which comprises at least one conversion pad comprising a stack of antenna-effect materials according to the invention and at least one filter comprising a stack of antenna-effect materials according to the invention is disposed on said light conversion module;
at least one sub-pixel includes at least one light conversion module which comprises at least one conversion pad comprising a stack of antenna-effect materials according to the invention and at least one filter different from that of the present invention, namely that it does not have a stack of antenna-effect materials according to the invention and that it comprises, for example a mixture of resin and pigments, is disposed on said light conversion module;
at least one sub-pixel comprises at least one light conversion module different from that of the present invention, namely that it is devoid of conversion pad(s) which comprises a stack of antenna-effect materials according to the invention and at least one filter which comprises a stack of antenna-effect materials according to the invention is disposed on said light conversion module;
at least one sub-pixel which does not have a light conversion module and at least one filter is disposed on the at least one light emitter which said at least one sub-pixel comprises, said filter comprising a stack of antenna-effect materials according to the invention.

In the context of the present invention, the optoelectronic device may comprise several light conversion modules which are disposed side-by-side and a filter is disposed on each of these light conversion modules. The conversion pads of the light conversion modules and/or said filters may comprise a stack of antenna-effect materials according to the invention.

When the light conversion module comprises several conversion pads or when several filters are disposed on the light conversion module, the optoelectronic device according to the invention may comprise several stacks which emit radiation of different colors because the rare earths may differ from one stack to another. By way of example, in the case of a light conversion module comprising two conversion pads, from light radiation emitted by a LED of blue color, depending on the rare earths present in the stacks of the two conversion pads, each of the two conversion pads will be able to re-emit a light radiation of a different color, for example green or red.

In the optoelectronic device, the stack may be integrated within a photo-or heat-sensitive resin, for example a resin chosen from vinyl ester, epoxy acrylate, polyimide, polyamide and unsaturated polyester resins. In one embodiment of the invention, the photo-or heat-sensitive resin is a SU-8 type resin (namely a resin composed of epoxy resin, propylene carbonate, the triaryl-sulfonium initiator and an organic solvent chosen from cyclopentanone or gamma-butyrolactone, depending on the formulation).

When the optoelectronic device comprises a light conversion module comprising several conversion pads or when several filters are disposed on the light conversion module, the stacks of conversion pads or filters may be separated from each other by light confinement walls which are capable of blocking the transmission of the light radiation emitted by the light emitter (preferably the LED), then that emitted by the stacks of antenna-effect materials according to the invention. These walls are made of an absorbent or reflective material.

Each stack of antenna-effect materials according to the invention may comprise:
a layer of chromophore covered with a layer of rare earth, or else
an alternation (or in other words a superposition) of layers of rare earth and of layers of chromophore.

A stack according to the invention may thus comprise:
between 1 and 50, preferably between 1 and 30, layers of chromophore, and
between 1 and 50, preferably between 1 and 30, layers of rare earth.

A stack advantageously comprises an alternation of layers of chromophore and of layers of rare earth because this makes it possible to increase the intensity of the light radiation re-emitted by the stack. Indeed, this increases the capture of the photons emitted by the light emitter (preferably the LED) by the layers of chromophore and therefore, by antenna effect, increases the intensity of the light radiation re-emitted by the rare earth. Also, a stack comprising a single layer of rare earth superimposed on a single layer of chromophore may not be sufficient to convert all the light emitted by the light emitter (preferably the LED). A stack of several layers of rare earth superimposed on layers of chromophore has the advantage that a greater number of photons emitted by the light emitter (preferably the LED) may be absorbed, which increases the efficiency of emission and the purity of the color emitted by the rare earth.

The thickness of the layer of rare earth may be comprised between 2 nm and 800 nm, preferably between 5 nm and 200 nm.

The thickness of the layer of chromophore may be comprised between 10 nm and 1 μm, preferably between 10 nm and 500 nm.

The thicknesses of the layers of rare earth and of chromophore are chosen appropriately to allow the energy transfer from the layer of chromophore to the layer of rare earth once the chromophore has collected the photons emitted by the light emitter (preferably the LED).

Advantageously, the choice of the thicknesses of the layers of rare earth and of chromophore is performed as follows:
the layers of chromophore have an appropriate thickness on the one hand to absorb a maximum of light and populate its excited states and on the other hand so that all the formed excitons may transfer their energy to the rare earth;
the layers of rare earth have an appropriate thickness to be accessible to the energy transfers.

This is why, advantageously, the stack comprises layers of chromophore and of rare earth in the range of a few nanometers.

Of course, the choice of the thicknesses of the layers of chromophore and of rare earth is within the reach of those skilled in the art.

The rare earth is preferably a lanthanide (as mentioned above with the exception of lanthanum (La) and lutetium (Lu)), and most particularly a lanthanide chosen from Tb, Eu, Er, Sm and Dy. The colors of the emission spectra of these lanthanides are particularly advantageous for the manufacture of an optoelectronic device such as a screen that includes LEDs. Indeed, their emission wavelengths are: Tb (545 nm), Eu (615 nm), Er (535 nm-550 nm), Sm (615 nm-620 nm) and Dy (580 nm). These lanthanides emit colors (for example red, green, yellow and cyan) which are hardly obtained directly from a LED with good emission efficiency. These lanthanides are therefore particularly suitable for converting a radiation of blue or near ultraviolet color into a radiation of red, green, yellow or cyan color.

In the context of the present invention, the term “chromophore” is understood to mean a compound capable of absorbing a large quantity of excitation light and of transferring the corresponding energy to the rare earth by antenna effect.

Preferably, the chromophore absorbs at a wavelength comprised between 100 nm and 500 nm.

Preferably, the chromophore comprises a system with conjugated TT bonds. Even more preferentially, the chromophore comprises one or more aromatic rings with optionally one or more heteroatoms (for example N, O or S).

The chromophore may for example be chosen from the compounds of chemical formulas (1) to (9) below:

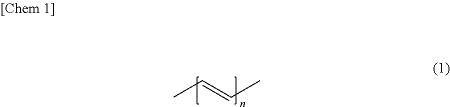

in which n is an integer comprised between 1 and 1000, preferably between 100 and 500,

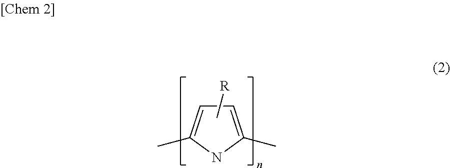

in which:
   n is an integer comprised between 1 and 1000, preferably between 100 and 500,
   R is chosen from hydrogen, an alkyl group comprising between 1 and 20 carbon atoms, a halogen, an alcohol, an ether, a thiol, an acrylate or a polyethylene glycol,

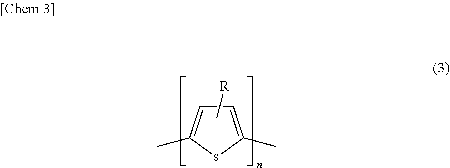

in which:
   n is an integer comprised between 1 and 1000, preferably between 100 and 500,
   R is chosen from hydrogen, an alkyl group comprising between 1 and 20 carbon atoms, a halogen, an alkoxy, a mercapto, an acrylate or a polyethylene glycol,

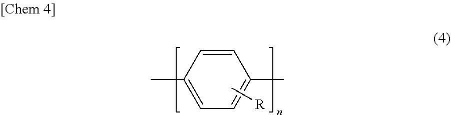

in which:
   n is an integer comprised between 1 and 1000, preferably between 100 and 500,
R is chosen from hydrogen, an alkyl group comprising between 1 and 20 carbon atoms, a halogen, an alkoxy, a mercapto, an acrylate or a polyethylene glycol,

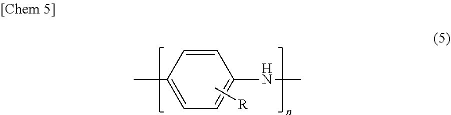

in which:
   n is an integer comprised between 1 and 1000, preferably between 100 and 500,
   R is chosen from hydrogen, an alkyl group comprising between 1 and 20 carbon atoms, a halogen, an alkoxy, a mercapto, an acrylate or a polyethylene glycol,

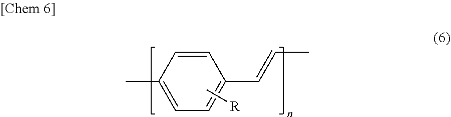

in which:
   n is an integer comprised between 1 and 1000, preferably between 100 and 500,
   R is chosen from hydrogen, an alkyl group comprising between 1 and 20 carbon atoms, a halogen, an alkoxy, a mercapto, an acrylate or a polyethylene glycol,

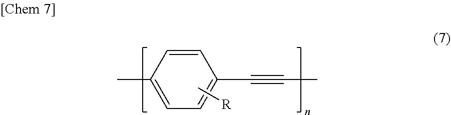

in which:
   n is an integer comprised between 1 and 1000, preferably between 100 and 500,
   R is chosen from hydrogen, an alkyl group comprising between 1 and 20 carbon atoms, a halogen, an alkoxy, a mercapto or a polyethylene glycol,

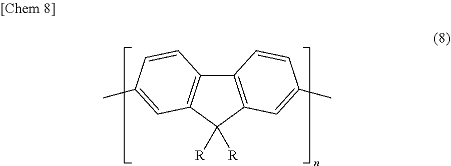

in which:
   n is an integer comprised between 1 and 1000, preferably between 100 and 500,
   R is chosen from hydrogen, an alkyl group comprising between 1 and 20 carbon atoms, a halogen, an alkoxy, a mercapto or a polyethylene glycol,

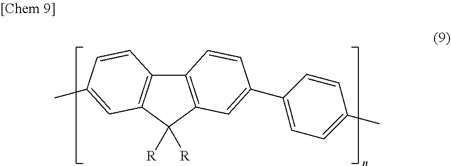

in which:
   n is an integer comprised between 1 and 1000, preferably between 100 and 500,
   R is chosen from hydrogen, an alkyl group comprising between 1 and 20 carbon atoms, a halogen, an alkoxy, a mercapto, an acrylate or a polyethylene glycol.

The chromophore may also be chosen from the following compounds: perylene-3,4,9,10-tetracarboxydiimide, perylene, naphthalimides, porphyrins, hexaphyrins and phthalocyanines.

The chromophore may be chosen from the compounds of chemical formulas (10) to (33) below:

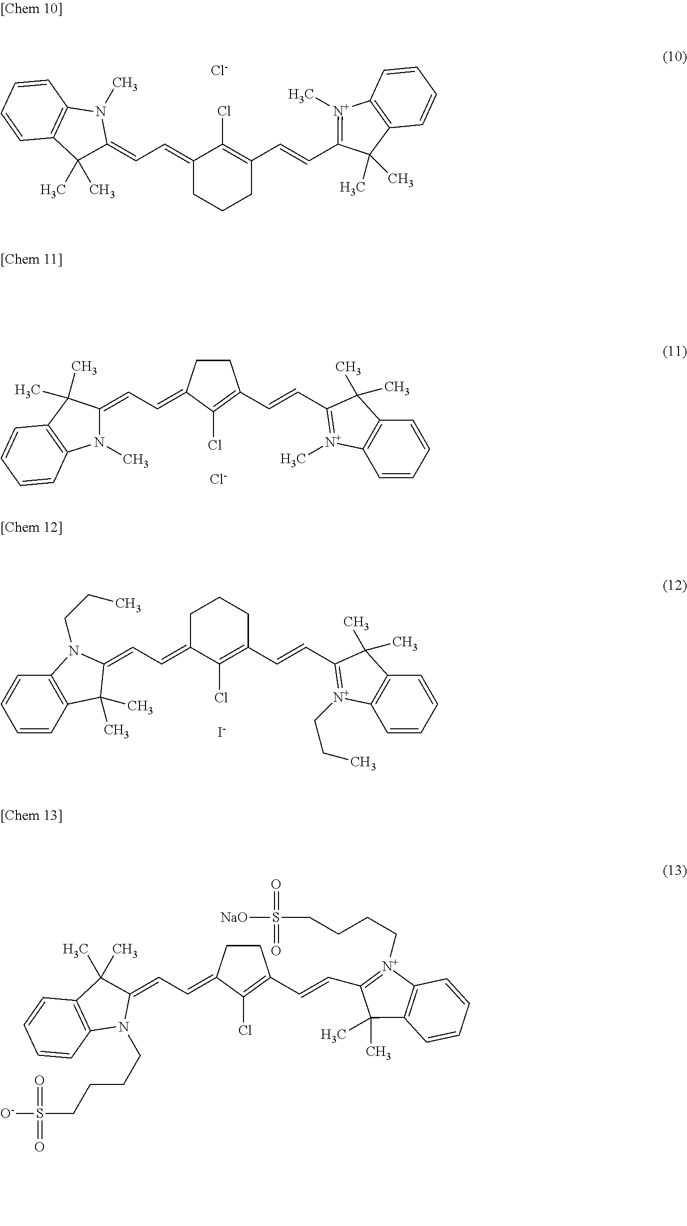

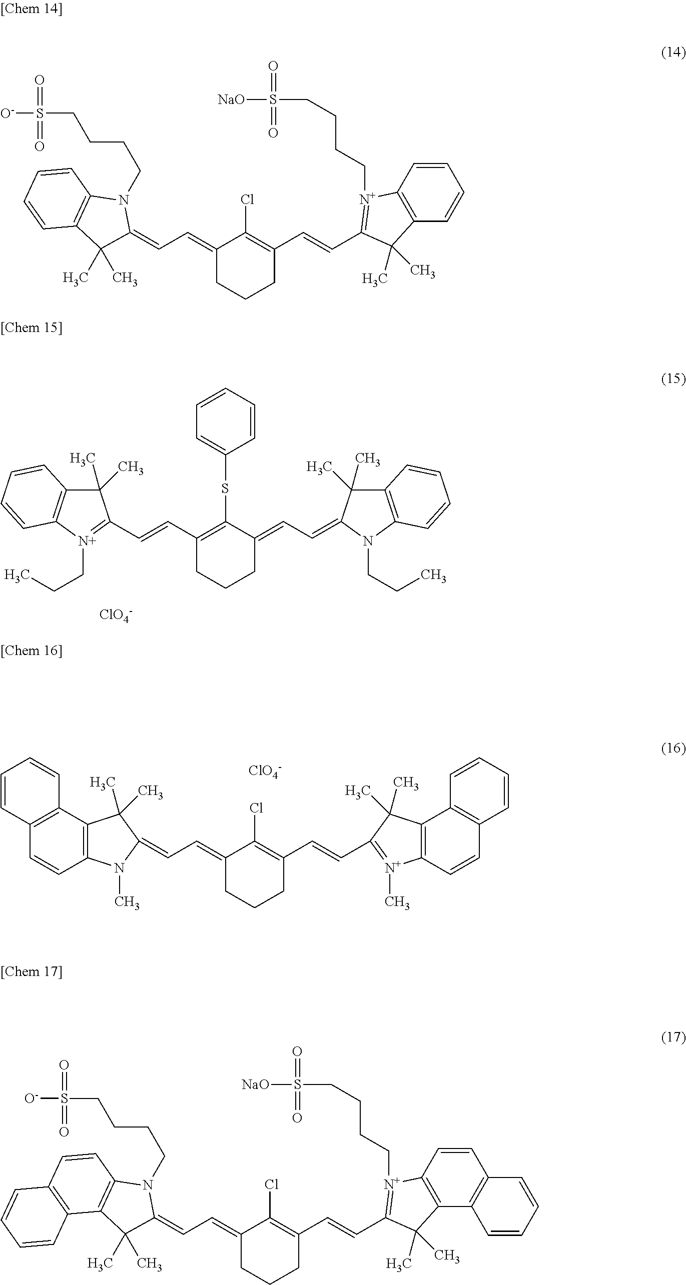

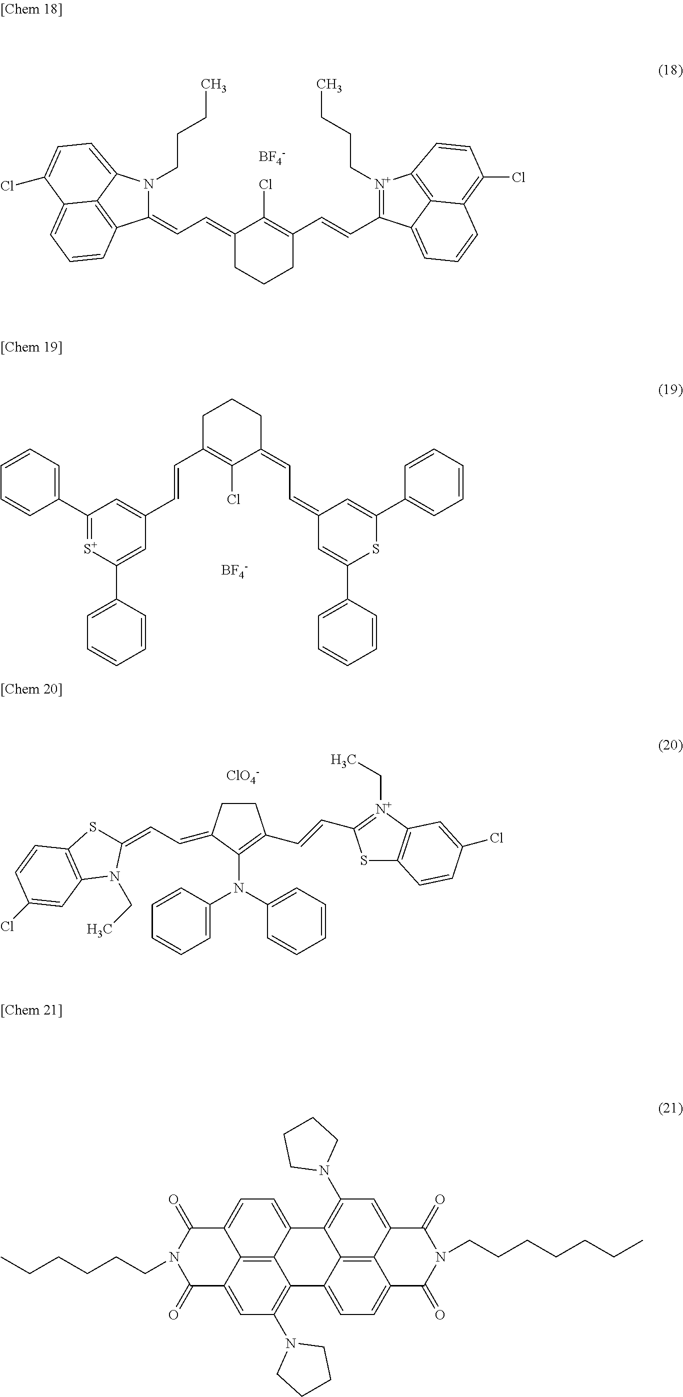

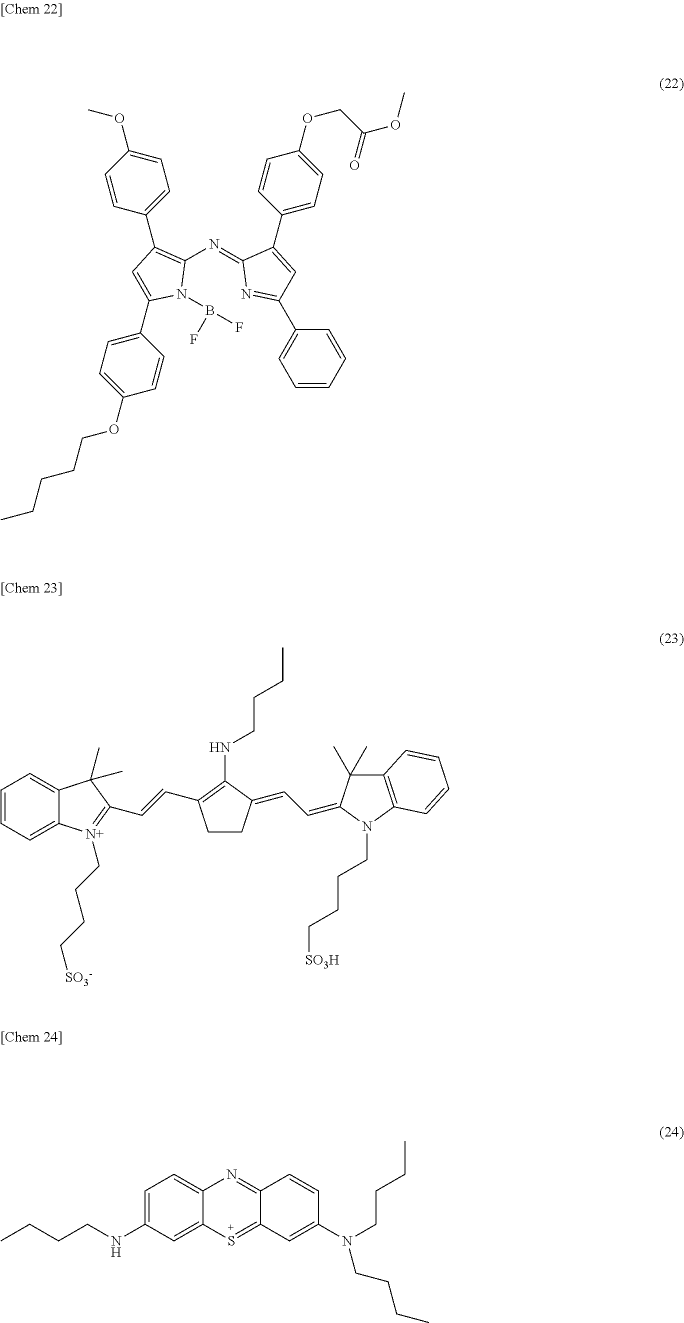

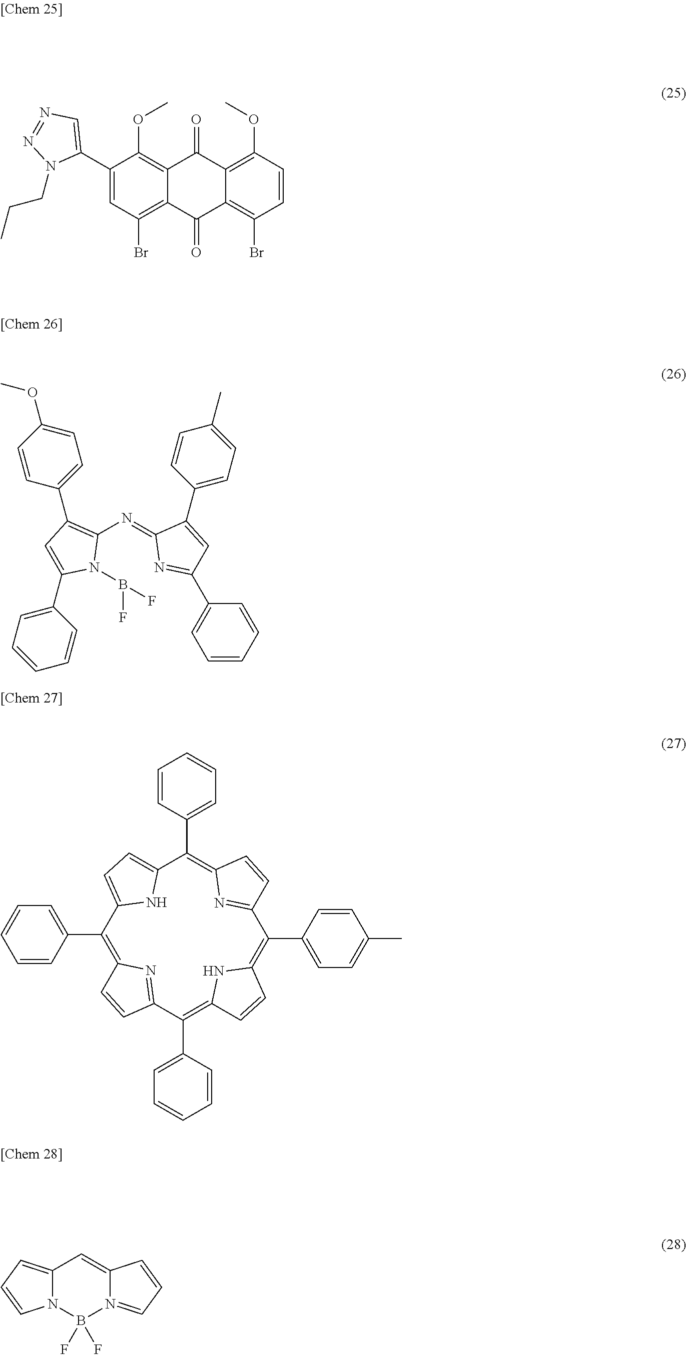

The chromophore of chemical formula (28) is boron-dipyrromethene.

The derivatives of boron-dipyrromethene are chromophores containing the chemical formula (28) and on which chemical groups of different nature have been grafted thereto. These groups aim to modulate some of its physico-chemical properties such as solubility or absorption wavelength. These groups may for example be chosen from polyaromatic groups, alkyl chains, alkoxy, polyethylene glycol chains and halogens.

Preferably, the chromophore is boron-dipyrromethene or one of its derivatives. Indeed, these compounds have an absorption up to 500 nm and a high molar absorption coefficient. These compounds are further easily modifiable to vary the absorption wavelength and adapt it to the light emitter (preferably a LED, and more preferably a LED of blue color). Moreover, they are particularly suitable to be associated with lanthanides emitting in the red and the near infrared in order to obtain an antenna effect. Finally, when the stack of at least one layer of rare earth on at least one layer of chromophore has for application a conversion pad, the presence of these compounds in the layer of chromophore is particularly advantageous because it prevents, during the antenna effect, the emission of any so-called parasitic emission spectra of certain lanthanides up to high wavelengths. These preferred chromophores thus limit the need to add filters to the light conversion modules and improve the efficiency of the light conversion.

The at least one light emitter of the optoelectronic device is preferably a LED. The optoelectronic device may comprise a plurality of LEDs.

The LEDs of the optoelectronic device according to the invention may comprise a wire, conical, frustoconical or pyramidal semiconductor element, for example a micro-wire or a nano-wire. They may also be planar, that is to say formed from a stack of flat semiconductor layers. Preferably, the LEDs are in the form of nano-wires or nano-pyramids.

In other words, the optoelectronic device may comprise a plurality of LEDs which are preferably three-dimensional LEDs of the nanostructure type such as nano-wires and nano-pyramids.

Advantageously, the at least one light emitter (1, 1a, 1b, 1c) emits a light radiation with a wavelength comprised between 100 nm and 500 nm (near ultraviolet-blue), preferably between 400 nm and 500 nm (blue) and the stack of antenna-effect materials according to the invention emits a light radiation with a wavelength comprised between 500 nm and 1000 nm (green-red, near infrared), preferably between 500 nm and 600 nm (green) or between 600 nm and 700 nm (red).

In the optoelectronic device according to the invention, said sub-pixels may be controlled independently of each other by activating or modifying the electric current applied to the at least one light emitter (preferably the at least one LED) that they comprise so as to modify the relative emission intensity of said sub-pixels.

The optoelectronic device according to the invention may comprise at least one pixel which comprises a 1st sub-pixel, a 2nd sub-pixel and a 3rd sub-pixel, preferably disposed side-by-side, each of said 1st, 2nd and 3rd sub-pixels comprises a light emitter (preferably a LED) which emits a light radiation of a given color. On the light emitter of the 1st sub-pixel a 1st stack of antenna-effect materials according to the invention as described above is disposed. On the light emitter of the 2nd sub-pixel a 2nd stack of antenna-effect materials according to the invention as described above is disposed. On the light emitter of the 3rd sub-pixel a layer of a resin transparent to light radiation (for example a SU-8 type resin) is disposed.

Said 1st and 2nd stack are conversion pads which constitute two light conversion modules. In other words, in this embodiment of the invention, the two light conversion modules each comprise a single conversion pad.

Preferably:
the light emitters of the 1st, 2nd and 3rd sub-pixels each emit a light radiation of blue color (for example a light radiation with a wavelength comprised between 400 nm and 500 nm);
the at least one layer of rare earth of the 1st stack is capable of emitting a light radiation of red color (for example a light radiation with a wavelength comprised between 600 nm and 700 nm);
the at least one layer of rare earth of the 2nd stack is capable of emitting a light radiation of green color (for example a light radiation with a wavelength comprised between 500 nm and 600 nm).

In this preferred embodiment of the invention, said pixel may thus emit 3 different colors, namely red, green and blue.

In this preferred embodiment of the invention, the 1st stack may comprise two layers of rare earth and the 2nd stack may comprise two layers of rare earth.

In addition, the 1st, 2nd and 3rd sub-pixels may be controlled independently of each other by activating or modifying the electric current applied to the light emitters they comprise in order to modify the relative emission intensity of each of the 1st, 2nd and 3rd sub-pixels.

Advantageously, the 1st stack and the 2nd stack are separated by a 1st light confinement wall and the 2nd stack and the layer of resin transparent to light radiation are separated by a 2nd light confinement wall. The material of the 1st and 2nd light confinement walls may be an absorbing or reflecting material, preferably a SU-8 type resin loaded with black pigments.

The invention also relates to a method for manufacturing a stack of antenna-effect materials according to the invention as described above and which is characterized in that it comprises at least the following steps:
the at least one layer of chromophore is carried out by molecular layer deposition (hereinafter abbreviated “MLD”) or by depositing a mixture comprising the chromophore and a photo-or heat-sensitive resin;
the at least one layer of rare earth is carried out by atomic layer deposition (hereinafter abbreviated “ALD”).

When the layer of chromophore is carried out by depositing a mixture comprising the chromophore and a photo-or heat-sensitive resin, said photo-or heat-sensitive resin may be chosen from vinyl ester, epoxy acrylate, polyimide, polyamide and unsaturated polyester resins.

The mixture may comprise in mass percentages:
between 5% and 50% of chromophore and
between 50% and 95% of photo-or heat-sensitive resin.

The deposition of this mixture may be carried out by photolithography. To do this, the mixture may, for example, be spread by spin coating or by slot die coating, then photopolymerized with an ultra-violet radiation.

In other embodiments of the invention, the deposition of this mixture may be carried out with other techniques such as ink jet, aerosol jet or screen printing.

The method for manufacturing the stack according to the invention thus has the following advantages:
good reliability and reproducibility, with ease of implementation and industrialization. Indeed, the techniques of deposition by ALD or MLD are recognized for their reliability and their reproducibility and are therefore very particularly appropriate for carrying out the depositions of the layers of rare earth and of chromophore of very low thickness (to generate the antenna effect), and in particular on LEDs in the form of nano-wires;
non-toxicity because the compounds implemented during said manufacturing process are rare earths and chromophores.

The manufacturing method according to the invention also has the advantage of being able to selectively carry out the stack of layers of chromophore and of rare earth on determined light emitters (preferably determined LEDs).

This is why, when the method for manufacturing a stack according to the invention is carried out selectively on at least one determined light emitter (preferably on at least one determined LED), for example on at least one determined light emitter of an optoelectronic device according to the invention as described above, said manufacturing method according to the invention may further include the following steps:
before the manufacture of said stack on the at least one determined light emitter, preferably on the at least one determined LED, a protection of the light emitters (preferably of the LEDs) on which said stack will not be carried out is performed, and
after said stack is carried out, a deprotection of the light emitters (preferably LEDs) on which said stack has not been carried out is performed.

The protection of the light emitters (preferably of the LEDs) may for example be carried out according to one of the following two protection methods.

The 1st protection method consists of the following steps:
a layer of SiN with a thickness which may be comprised between 100 nm and 100 μm is deposited on all the light emitters (preferably the LEDs), and this by a deposition technique chosen, for example, from ALD, chemical vapor deposition (known by the acronym “CVD”) or plasma-enhanced chemical vapor deposition (known by the acronym “PECVD”);
a layer of SiO₂ with a thickness which may be comprised between 100 nm and 100 μm is deposited on the layer of SiN of all the light emitters (preferably the LEDs) by a deposition technique chosen, for example, from ALD, CVD or PECVD;
the layer of SiO₂ is removed by laser ablation from the at least one determined light emitter (preferably a LED) on which the stack will be carried out;
a self-assembled monolayer (hereinafter abbreviated “SAM”) of silane is deposited on the remaining layers of SiO₂, namely the layers of SiO₂ of the light emitters, preferably of the LEDs, on which the stack will not be carried out, so as to protect the light emitters (preferably the LEDs) on which the stack will not be performed.

The SAM of silane is thus grafted to the layer of SiO₂.

The SAM of silane is advantageously obtained from a silylating agent chosen from alkyltrichlorosilanes, alkyltrimethoxysilanes and alkyltriethoxysilanes, preferably the alkyl group having at least 12 carbon atoms. For example, it may be octadecyltrimethoxysilane.

According to this 1st protection method, the light emitters (preferably the LEDs) on which the stack must not be carried out are thus protected because they are covered with a layer of SiO2 on which a SAM of silane has been grafted.

The 2nd protection method consists in depositing on the light emitters (preferably the LEDs) on which the stack will not be carried out (in other words the light emitters, preferably the LEDs, to be protected) a layer of a photo-or heat-sensitive resin, for example a resin chosen from vinyl ester, epoxy acrylate, polyimide, polyamide or unsaturated polyester resins, with a thickness which may be comprised between 100 nm and 1 μm. In one embodiment of the invention, the resin is a SU-8 type resin.

Then, the deprotection of the light emitters, preferably of the LEDs, on which the stack has not been carried out may be performed in the following way:
if the protection has been implemented with the combination of a layer of SiN, SiO₂ and a SAM of silane, the deprotection of the light emitters on which the stack has not been carried out is performed by removing by laser ablation the layer of SiO₂ and the SAM of silane which have been deposited on these light emitters or else by removing only the SAM of silane by hydrolysis in an acidic or basic environment, for example by using a mixture of n-propanol/sulphuric acid, ethanol/sulphuric acid or butylamine/butylamine hydrochloride♯this 2nd alternative is a so-called “soft” deprotection method which is simpler to implement than the laser ablation;
If the protection step was implemented with a layer of photo-or heat-sensitive resin, this layer is removed using a plasma, for example a plasma containing a mixture of dioxygen and carbon tetrafluoride.

These protection and deprotection steps may thus be implemented several times to carry out, on determined light emitters (preferably LEDs) constituting sub-pixels, stacks of antenna-effect materials according to the invention of different natures which constitute light conversion modules with a conversion pad so that the radiation emitted by these different stacks are of different colors, and this at determined locations of the matrix of pixels formed by the plurality of sub-pixels.

The invention will be better understood with the aid of the detailed description which is set out below with reference to the appended drawing showing, by way of non-limiting example, embodiments of light conversion modules and of a filter on a light conversion module of optoelectronic devices according to the invention.

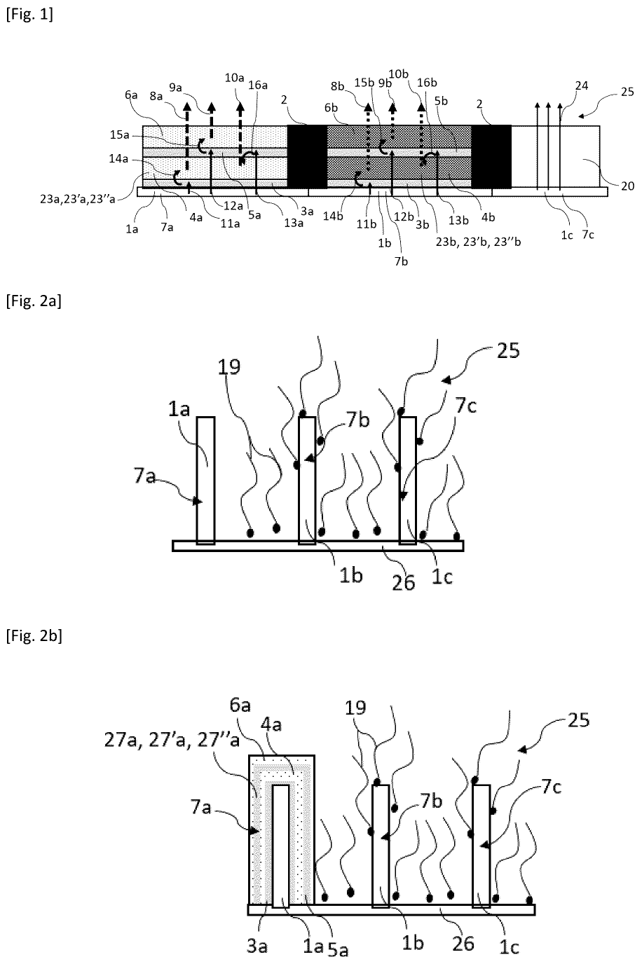

FIG. 1 represents a schematic cross-section of a pixel of an optoelectronic device according to the invention.

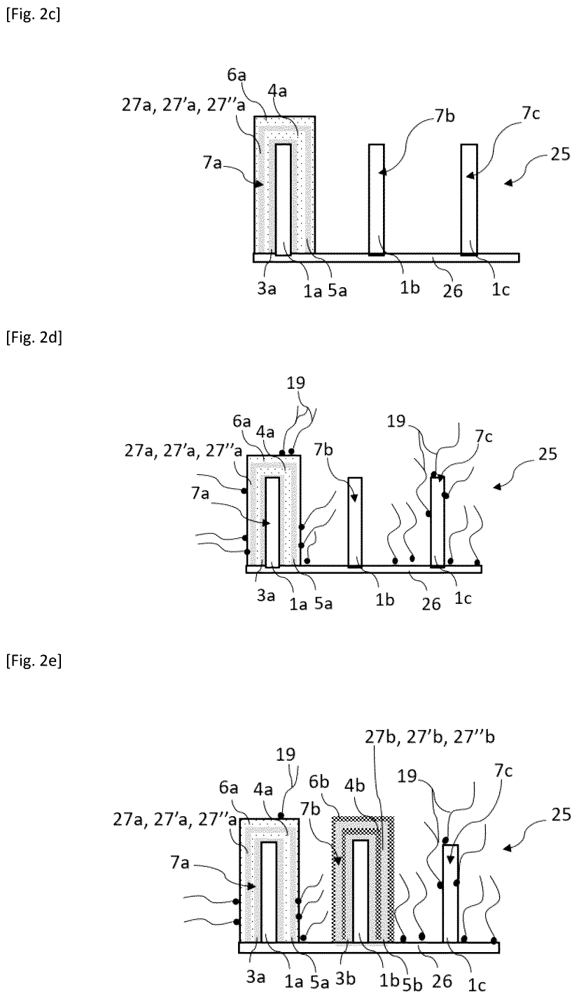

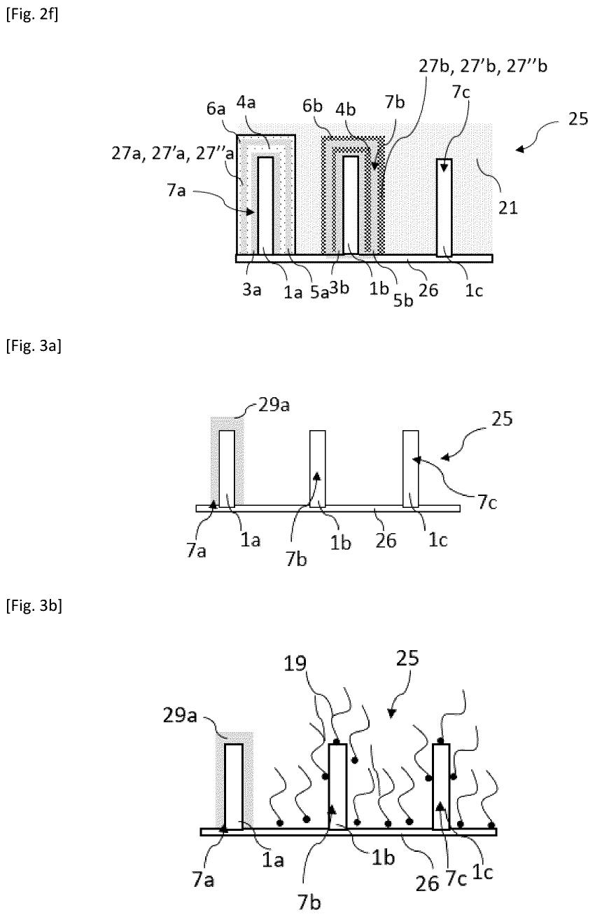

FIG. 2a represents a schematic cross-section of a pixel of an optoelectronic device according to the invention during a step of a 1st embodiment of the method for manufacturing 2 stacks according to the invention of 2 conversion pads of 2 light conversion modules.

FIG. 2b represents a schematic cross-section of the pixel during the next step to that represented in FIG. 2a.

FIG. 2c represents a schematic cross-section of the pixel during the next step to that represented in FIG. 2b.

FIG. 2d represents a schematic cross-section of the pixel during the next step to that represented in FIG. 2c.

FIG. 2e represents a schematic cross-section of the pixel during the next step to that represented in FIG. 2d.

FIG. 2f represents a schematic cross-section of the pixel during the next step to that represented in FIG. 2e.

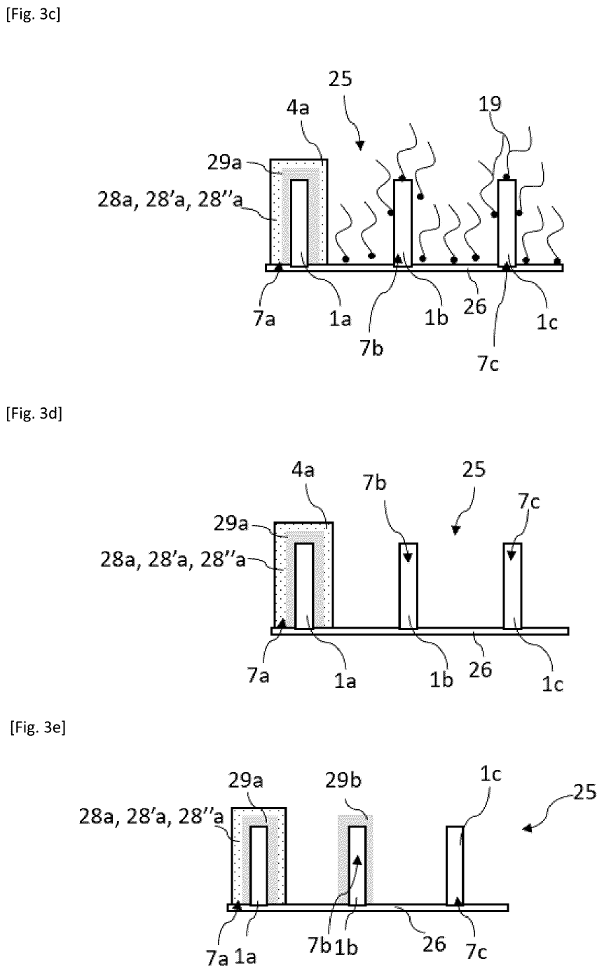

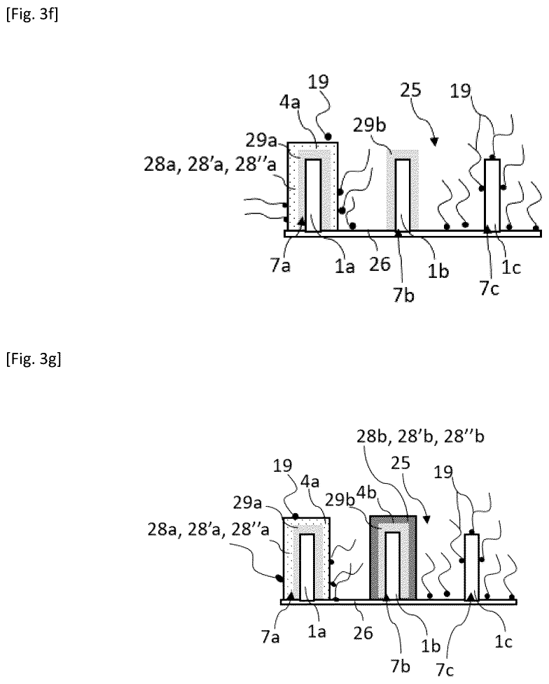

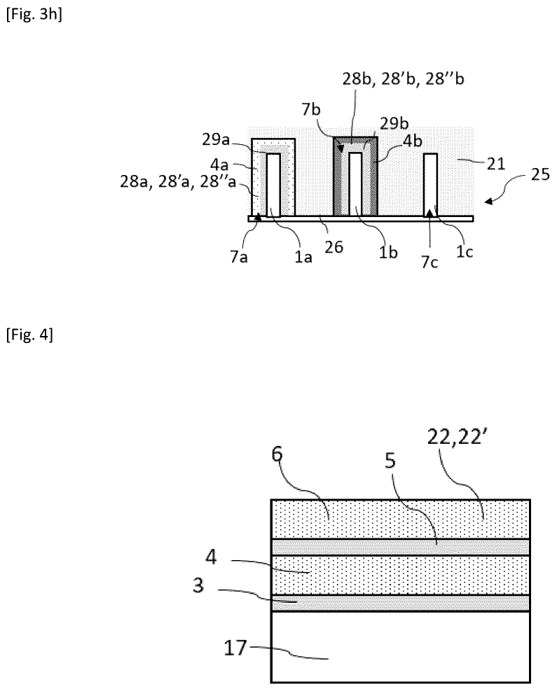

FIG. 3a represents a schematic cross-section of a pixel of an optoelectronic device according to the invention during a step of a 2nd embodiment of the method for manufacturing 2 stacks according to the invention of 2 conversion pads of 2 light conversion modules.

FIG. 3b represents a schematic cross-section of the pixel during the next step to that represented in FIG. 3a.

FIG. 3c represents a schematic cross-section of the pixel during the next step to that represented in FIG. 3b.

FIG. 3d represents a schematic cross-section of the pixel during the next step to that represented in FIG. 3c.

FIG. 3e represents a schematic cross-section of the pixel during the next step to that represented in FIG. 3d.

FIG. 3f represents a schematic cross-section of the pixel during the next step to that represented in FIG. 3e.

FIG. 3g represents a schematic cross-section of the pixel during the next step to that represented in FIG. 3f.

FIG. 3h represents a schematic cross-section of the pixel during the next step to that represented in FIG. 3g.

FIG. 4 represents a schematic cross-section of a light conversion module on which is disposed a filter which comprises a stack of antenna-effect materials according to the invention.

FIG. 1 represents a schematic cross-section of a pixel 25 of an optoelectronic device according to the invention (not represented). The pixel 25 comprises 3 sub-pixels 7a, 7b and 7c disposed side-by-side and which respectively include a planar LED 1a, 1b and 1c each emitting a radiation of blue color.

On the LED 1a is disposed a 1st stack 23a comprising a 1st layer of a chromophore 3a (boron-dipyrromethene) with a thickness of 50 nm and which is covered with a 1st layer of a rare earth 4a (Eu₂O₃) with a thickness of 50 nm. This 1st layer 4a is covered with a 2nd layer of a chromophore 5a (boron-dipyrromethene) with a thickness of 50 nm which is itself covered with a 2nd layer of a rare earth 6a (Eu₂O₃) with a thickness of 50 nm.

The 1st and 2nd layers of rare earth 4a and 6a are capable of emitting a light radiation of red color. The 1st stack 23a is a conversion pad 23′a which constitutes a 1st light conversion module 23″a. In other words, the light conversion module 23″a comprises a single conversion pad 23′a which is in the form of the 1st stack 23a.

On the LED 1b is disposed a 2nd stack 23b comprising a 1st layer of a chromophore 3b (boron-dipyrromethene), with a thickness of 50 nm and which is covered with a 1st layer of a rare earth 4b (Tb₂O₃) with a thickness of 50 nm. This 1st layer 4b is covered with a 2nd layer of a chromophore 5b (boron-dipyrromethene) with a thickness of 50 nm and which is itself covered with a 2nd layer of a rare earth 6b (Tb₂O₃) with a thickness of 50 nm.

The 1st and 2nd layers of rare earth 4b and 6b are capable of emitting a light radiation of green color. The 2nd stack 23b is a conversion pad 23′b which constitutes a 2nd light conversion module 23″b. In other words, the light conversion module 23″b comprises a single conversion pad 23′b which is in the form of the 2nd stack 23b.

The 1st and 2nd stacks 23a and 23b were integrated in a SU-8 type resin not represented on FIG. 1.

On the LED 1c is disposed a layer 20 of a SU-8 type resin (namely a transparent resin) and is therefore devoid of a stack of layers of chromophore and of rare earth.

The 1st and 2nd stacks 23a and 23b are separated by a 1st light confinement wall 2. The 2nd stack 23b and the layer 20 of resin are separated by a 2nd light confinement wall. These 1st and 2nd light confinement walls 2 are made of an absorbent material which is a SU-8 type resin loaded with black pigments.

The conversion of blue color emitted by the LEDs 1a and 1b respectively into red and green colors is carried out in the following way via an antenna effect.

The LED 1a emits a 1st light radiation 11a in the 1st layer of chromophore 3a which will absorb the light energy and populate its excited states.

Then, an energy transfer 14a takes place towards the 1st layer of rare earth 4a thus allowing the effective population of its excited states. Finally, the excited states of the rare earth are relaxed by a radiative process, leading to the emission of a 1st light radiation 8a of red color out of the 1st stack 23a.

The LED 1a also emits a 2nd light radiation 12a in the 2nd layer of chromophore 5a which will absorb the light energy and populate its excited states. Then, an energy transfer 15a takes place towards the 2nd layer of rare earth 6a thus allowing the effective population of its excited states. Finally, the excited states of the rare earth are relaxed by a radiative process, leading to the emission of a 2nd light radiation 9a of red color out of the 1st stack 23a.

The LED 1a also emits a 3rd light radiation 13a in the 2nd layer of chromophore 5a which will absorb the light energy and populate its excited states. Then, an energy transfer 16a takes place towards the 1st layer of rare earth 4a thus allowing the effective population of its excited states. Finally, the excited states of the rare earth are relaxed by a radiative process, leading to the emission of a 3rd light radiation 10a of red color out of the 1st stack 23a.

The LED 1b emits a 1st light radiation 11b in the 1st layer of chromophore 3b which will absorb the light energy and populate its excited states. Then, an energy transfer 14b takes place towards the 1st layer of rare earth 4b thus allowing the effective population of its excited states. Finally, the excited states of the rare earth are relaxed by a radiative process, leading to the emission of a 1st light radiation 8b of green color out of the 2nd stack 23b.

The LED 1b also emits a 2nd light radiation 12b in the 2nd layer of chromophore 5b which will absorb the light energy and populate its excited states. Then, an energy transfer 15b takes place towards the 2nd layer of rare earth 6b thus allowing the effective population of its excited states. Finally, the excited states of the rare earth are relaxed by a radiative process, leading to the emission of a 2nd light radiation 9b of green color out of the 2nd stack 23b.

The LED 1c also emits a 3rd light radiation 13b in the 2nd layer of chromophore 5b which will absorb the light energy and populate its excited states. Then, an energy transfer 16b takes place towards the 1st layer of rare earth 4b thus allowing the effective population of its excited states. Finally, the excited states of the rare earth are relaxed by a radiative process, leading to the emission of a 3rd light radiation 10b of green color out of the 2nd stack 23b.

Finally, the LED 1c emits light radiation 24 into the layer 20 of SU-8 type resin which is transparent. These light rays 24 are therefore not altered at the output of the layer 20 of resin.

Because the sub-pixels 7a and 7b each comprise a light conversion module 23″a and 23″b comprising a conversion pad 23′a and 23′b which respectively comprises a 1st stack 23a and a 2nd stack 23b, the pixel 25 is thus configured to emit 3 different colors, namely red, green and blue.

As explained above, the sub-pixels 7a, 7b and 7c may be controlled independently of each other by activating or modifying the electric current applied to each LED 1a, 1b and 1c in order to modify the relative emission intensity of each sub-pixel 7a, 7b and 7c.

FIGS. 2a to 2f represent schematic cross-sections of a pixel 25 comprising three sub-pixels 7a, 7b and 7c during the different steps of a 1st embodiment of the method for manufacturing 2 stacks 27a and 27b according to the invention of 2 conversion pads 27′a and 27′b of 2 light conversion modules 27″a and 27″b.

Initially, a pixel 25 was available which comprised 3 sub-pixels 7a, 7b 7c which respectively included a LED 1a, 1b and 1c in the form of a nano-wire each emitting a radiation of blue color and which rested on a support 26 of silicon on which said LEDs 7a, 7b and 7c had been generated.

A layer of SiN, then a layer of SiO₂ were deposited on the surface of LEDs 1a, 1b and 1c by ALD. These 2 layers each had a thickness of 100 nm. These layers of SiN and SiO₂ are not represented on the figures.

The layer of SiO₂ deposited on the surface of the LED 1a was removed by laser ablation.

Then, a SAM of silane obtained from the silylating agent octadecyltrimethoxysilane 19 was formed on the surface of the layer of SiO₂ present on the LEDs 1b and 1c. This SAM of silane was obtained by immersing the pixel 25 in a solution of said silylating agent in toluene at room temperature, under an inert atmosphere, for 1 hour.

On FIG. 2a are thus represented schematically the 3 LEDs 1a, 1b and 1c and the SAM of silane 19 which has been grafted onto the layer of SiO₂ (not represented) on the surface of the LEDs 1b and 1c. In this way, the LEDs 1b and 1c have been protected to be able to selectively carry out a stack 27a of layers of chromophore 3a and 5a and of layers of rare earth 4a and 6a only on the 1st LED 1a as explained just below.

Indeed, the following successive depositions were carried out on the 1st LED 1a in accordance with the method for manufacturing the stack 27a according to the invention:
the deposition of a 1st layer of layer 3a of chromophore (boron-dipyrromethene) and with a thickness of 50 nm by MLD;
the deposition of a 1st layer of layer 4a of rare earth (Eu₂O₃) and with a thickness of 50 nm by ALD;
the deposition of a 2nd layer of layer 5a of chromophore (boron-dipyrromethene) and with a thickness of 50 nm by MLD;
the deposition of a 2nd layer of layer 6a of rare earth (Eu₂O₃) and with a thickness of 50 nm by ALD.

At the end of these depositions of layers 3a to 6a forming the stack 27a, the pixel 25 as represented on FIG. 2b was obtained.

The layer of SiO₂ (not represented) and the SAM of silane 19 were then removed from the 2nd and 3rd LEDs 1b and 1c by laser ablation so as to obtain the pixel 25 as represented on FIG. 2c.

Then, these same steps were carried out again to selectively protect this time the LEDs 1a and 1c and perform a stack 27b of layers of chromophore 3b and 5b and of layers of rare earth 4b and 6b on the LED 1b. To do this, a layer of SiO₂ was deposited on the surface of the LEDs 1a,

1b and 1c, as explained above.

The layer of SiO₂ deposited on the surface of the LED 1b has been removed as explained above.

Then, a SAM of silane 19 was formed on the surface of the layer of SiO₂ present on the LEDs 1a and 1c, as explained above.

On FIG. 2d are thus represented schematically the 3 LEDS 1a, 1b and 1c and the SAM of silane 19 which has thus been grafted onto the layer of SiO₂ (not represented) on the surface of the LEDs 1a and 1c. In this way, the LEDs 1a and 1c have been protected be able to carry out the stack 27b of layers of chromophore 3b and 5b and of layers of rare earth 4b and 6b only on the 2nd LED 1b as explained just below.

Indeed, the following successive depositions were carried out on the 2nd LED 1b in accordance with the method for manufacturing the stack 27b according to the invention:
the deposition of a 1st layer of layer 3b of chromophore (boron-dipyrromethene) and with a thickness of 50 nm by MLD;
the deposition of a 1st layer of layer 4b of rare earth (Tb₂O₃) and with a thickness of 50 nm by ALD;
the deposition of a 2nd layer of layer 5b of chromophore (boron-dipyrromethene) and with a thickness of 50 nm by MLD;
the deposition of a 2nd layer of layer 6b of rare earth (Tb₂O₃) and with a thickness of 50 nm by ALD.

At the end of these depositions of the layers 3b to 6b, the pixel 25 was obtained as represented on FIG. 2e.

The layer of SiO₂ and the SAM of silane 19 were then removed from the LEDs 1a and 1c as explained above. Then, a SU-8 type resin 21 was added so as to cover the LEDs 1a, 1b and 1c and to obtain the pixel 25 represented on FIG. 2f.

The superposition of the layers 3a, 4a, 5a and 6a forms the 1st stack 27a which is a conversion pad 27′a which constitutes a 1st light conversion module 27″a and which is capable of converting the light radiation of blue color of the LED 1a of the sub-pixel 7a into a light radiation of red color. In other words, the light conversion module 27″a comprises a single conversion pad 27′a which is in the form of the stack 27a.

The superposition of the layers 3b, 4b, 5b and 6b forms the 2nd stack 27b which a conversion pad 27′b which constitutes a 2nd light conversion module 27″b and which is capable of converting the light radiation of blue color of the LED 1b of the sub-pixel 7b in a light radiation of green color. In other words, the light conversion module 27″b comprises a single conversion pad 27′b which is in the form of the stack 27b.

Thus, the pixel 25 represented on FIG. 2f comprises three sub-pixels 7a, 7b and 7c which, thanks to the 1st and 2nd light conversion modules 27″a and 27″b emit light rays of different colors, respectively red, green and blue, whereas they respectively comprise a LED 1a, 1b and 1c all emitting a light radiation of blue color.

FIGS. 3a to 3h represent schematic cross-sections of a pixel 25 comprising three sub-pixels 7a, 7b and 7c during the steps of a 2nd embodiment of the method for manufacturing 2 stacks according to the invention 28a and 28b of 2 conversion pads 28′a and 28′b of 2 light conversion modules 28″a and 28″b.

Initially, a pixel 25 was available comprising 3 sub-pixels 7a, 7b and 7c which respectively included a LED 7a, 7b and 7c in the form of a nano-wire each emitting a radiation of blue color and which were fastened on a support 26 of silicon on which said LEDs 7a, 7b and 7c had been generated.

A layer 29a with a thickness of 100 nm comprising a mixture containing, in mass percentages, 40% of chromophore (boron-dipyrromethene) and 60% of a SU-8 type resin, was deposited by photolithography on the 1st LED 1a so as to obtain the pixel 25 as represented on FIG. 3a.

Next, a layer of SiN, then a layer of SiO₂ were deposited on the surface of the LEDs 1b and 1c, as explained above for the 1st embodiment of the manufacturing method, in order to protect said LEDs 1b and 1c. These layers of SiN and SiO₂ are not represented on the figures.

Then, a SAM of silane 19 was formed on the surface of the layer of SiO₂ present on the LEDs 1b and 1c, as explained above for the 1st embodiment of the manufacturing method.

On FIG. 3b are thus represented schematically the 3 LEDS 1a, 1b and 1c and the SAM of silane 19 which has been grafted onto the layer of SiO₂ (not represented) on the surface of the LEDs 1b and 1c. As explained above, the LED 1a has been covered with a layer 29a comprising the mixture of chromophore and of the SU-8 type resin.

The deposition of a layer 4a of rare earth Eu₂O₃ and with a thickness of 50 nm was performed by ALD on the layer 29a comprising the mixture of chromophore and of the SU-8 type resin of the 1st LED 1a. At the end of this deposition of the layer 4a, the pixel 25 as represented on FIG. 3c was obtained.

The superposition of the layers 29a and 4a forms a 1st stack 28a which is a conversion pad 28′a which constitutes a 1st light conversion module 28″a and which is capable of converting the radiation of blue light of the LED 1a of the sub-pixel 7a in a light radiation of red color. In other words, the light conversion module 28″a comprises a single conversion pad 28′a which is in the form of the stack 28a.

The layer of SiO₂ and the SAM of silane 19 were then removed from the 2nd and 3rd LEDs 1b and 1c as explained above for the 1st embodiment of the manufacturing method so as to obtain the pixel 25 as represented on FIG. 3d.

A layer 29b with a thickness of 100 nm comprising a mixture containing, in mass percentages, 40% of chromophore (boron-dipyrromethene) and 60% of a SU-8 type resin, was deposited by photolithography on the 2nd LED 1b so as to obtain the pixel 25 as represented on FIG. 3e.

Next, a layer of SiO₂ was deposited on the surface of the LEDs 1a and 1c as explained above for the 1st embodiment of the manufacturing method, in order to protect them.

Then, a SAM of silane 19 was formed on the surface of the layer of SiO₂ present on the LEDs 1a and 1c, as explained above.

On FIG. 3f are thus represented schematically the 3 LEDs 1a, 1b and 1c and the SAM of silane 19 which has thus been grafted onto the layer of SiO₂ (not represented) on the surface of the LEDs 1a and 1c. In this way, the LEDs 1a and 1c have been protected.

The deposition of a layer 4b of rare earth (Tb₂O₃) and with a thickness of 50 nm was performed by ALD on the layer 29b comprising the mixture of chromophore and of the SU-8 type resin of the 2nd LED 1b. At the end of this deposition of the layer 4b, the pixel 25 as represented on FIG. 3g was obtained.

The superposition of the layers 29b to 4b forms a 2nd stack 28b which is a conversion pad 28′b which constitutes a 2nd light conversion module 28″b and which is capable of converting the light radiation of blue color of the LED 1b of the sub-pixel 7b in a light radiation of green color. In other words, the light conversion module 28″b comprises a single conversion pad 28′b which is in the form of the stack 28b.

The layer of SiO₂ and the SAM of silane 19 were then removed from the LEDs 1a and 1c as described above for the 1st embodiment of the manufacturing method.

Then, a SU-8 type resin 21 was added so as to cover the LEDs 1a, 1b and 1c and to obtain the pixel 25 represented on FIG. 3h.

Thus, the pixel 25 represented on FIG. 3h comprises three sub-pixels 7a, 7b and 7c which, thanks to the 1st and 2nd light conversion modules 28″a and 28″b emit light rays of different colors, respectively red, green and blue, whereas they respectively comprise a LED 1a, 1b and 1c all emitting a light radiation of blue color.

FIG. 4 represents a schematic cross-section of a light conversion

module 17 of an optoelectronic device (not represented), said light conversion module 17 not comprising a stack according to the present invention. Indeed, it consists of quantum dots of the InP type with a size comprised between 3 nm and 10 nm incorporated in a photo-or heat-sensitive resin which is a SU-8 type resin.

This light conversion module 17 is configured to convert a light radiation of blue color emitted by a LED (not represented on FIG. 4) of a sub-pixel (not represented on FIG. 4) into a light radiation of red color.

On said light conversion module 17 is disposed a filter 22′.

The filter 22′ comprises a stack 22 integrated in a SU-8 type resin (not represented on FIG. 4) and which comprises a 1st layer of a chromophore 3 (boron-dipyrromethene) with a thickness of 100 nm and which is covered with a 1st layer of a rare earth 4 (Eu₂O₃) with a thickness of 50 nm. This 1st layer 4 is covered with a 2nd layer of a chromophore 5 (boron-dipyrromethene) with a thickness of 100 nm which is itself covered with a 2nd layer of a rare earth 6 (Eu₂O₃) with a thickness of 50 nm. The 1st and 2nd layers of rare earth 4 and 6 are capable of emitting a light radiation of red color.

The filter 22 filters the residual blue light coming from the so-called “conventional” light conversion module 17 (namely a light conversion module which contains quantum dots) so that a light radiation of red color (not represented on FIG. 4) is emitted out of the filter 22.

Thus, the design of a stack of layers of rare earth on layers of chromophore is perfectly appropriate both for carrying out light conversion modules and filters with which optoelectronic devices are provided.

FIG. 4 illustrates one form of implementation of a filter comprising a stack according to the invention. Of course, other forms of implementation of such a filter in an optoelectronic device according to the invention can be envisaged within the scope of the invention.

For example, an optoelectronic device may comprise several light conversion modules disposed side-by-side, for example light conversion modules such as the one represented on FIG. 4. A filter comprising a stack of antenna-effect materials according to the invention may be disposed on each of these light conversion modules.

In addition, still within the scope of the invention, a filter comprising a stack of antenna-effect materials according to the invention may be disposed directly on the light emitter (preferably the LED). In other words, the light conversion module is optional.

1. A stack of antenna-effect materials, wherein the stack comprises at least one layer of rare earth on at least one layer of chromophore, the rare earth being different from lutetium and lanthanum.

2. The stack according to claim 1, wherein it is configured so that an energy transfer takes place between the materials forming the layers, when the stack is subjected to a light excitation.

3. The stack according to claim 1, wherein the chromophore is a compound capable of absorbing a large quantity of excitation light and transferring the energy corresponding to the rare earth by antenna effect.

4. The stack according to claim 1, wherein it comprises:
between 1 and 50 layers of chromophore, and
between 1 and 50 layers of rare earth.

5. The stack according to claim 1, wherein:
the thickness of the layer of rare earth is comprised between 2 nm and 800 nm;
the thickness of the layer of chromophore is comprised between 10 nm and 1 μm.

6. The stack according to claim 1, wherein the rare earth is a lanthanide.

7. The stack according to claim 1, wherein the chromophore comprises a system with conjugated π bonds.

8. The stack according to claim 7, wherein the chromophore is chosen from the compounds of chemical formulas (1) to (9) below: 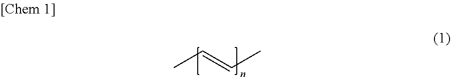
in which n is an integer comprised between 1 and 1000, 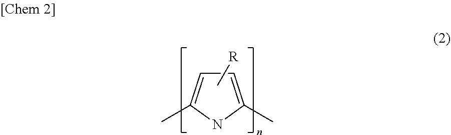
in which:
n is an integer comprised between 1 and 1000,
R is chosen from hydrogen, an alkyl group comprising between 1 and 20 carbon atoms, a halogen, an alcohol, an ether, a thiol, an acrylate or a polyethylene glycol, 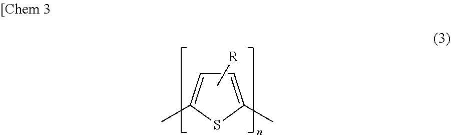
in which:
n is an integer comprised between 1 and 1000,
R is chosen from hydrogen, an alkyl group comprising between 1 and 20 carbon atoms, a halogen, an alkoxy, a mercapto, an acrylate or a polyethylene glycol, 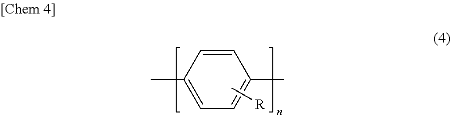
in which:
n is an integer comprised between 1 and 1000,
R is chosen from hydrogen, an alkyl group comprising between 1 and 20 carbon atoms, a halogen, an alkoxy, a mercapto, an acrylate or a polyethylene glycol, 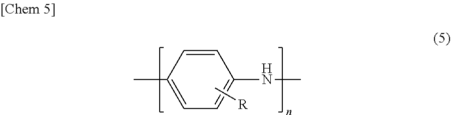
in which:
n is an integer comprised between 1 and 1000,
R is chosen from hydrogen, an alkyl group comprising between 1 and 20 carbon atoms, a halogen, an alkoxy, a mercapto, an acrylate or a polyethylene glycol, 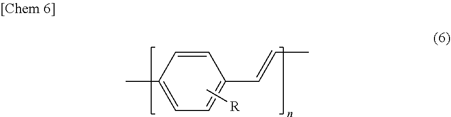
in which:
n is an integer comprised between 1 and 1000,
R is chosen from hydrogen, an alkyl group comprising between 1 and 20 carbon atoms, a halogen, an alkoxy, a mercapto, an acrylate or a polyethylene glycol, 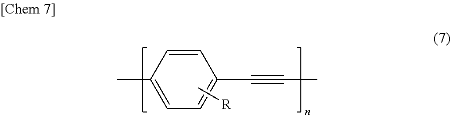
in which:
n is an integer comprised between 1 and 1000,
R is chosen from hydrogen, an alkyl group comprising between 1 and 20 carbon atoms, a halogen, an alkoxy, a mercapto or a polyethylene glycol, 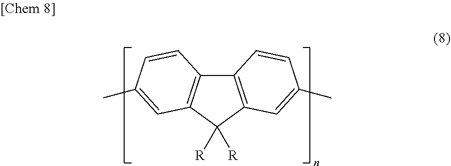
in which:
n is an integer comprised between 1 and 1000,
R is chosen from hydrogen, an alkyl group comprising between 1 and 20 carbon atoms, a halogen, an alkoxy, a mercapto or a polyethylene glycol, 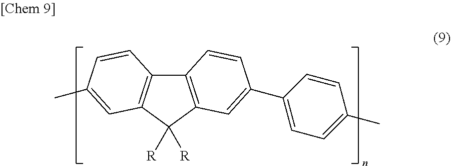
in which:
n is an integer comprised between 1 and 1000,
R is chosen from hydrogen, an alkyl group comprising between 1 and 20 carbon atoms, a halogen, an alkoxy, a mercapto, an acrylate or a polyethylene glycol.

9. The stack according to claim 7, wherein the chromophore is chosen from perylene-3,4,9,10-tetracarboxydiimide, perylene, naphthalimides, porphyrins, hexaphyrins and phthalocyanines.

10. The stack according to claim 7, wherein the chromophore is boron-dipyrromethene or one of its derivatives.

11. An optoelectronic device comprising at least one light emitter, wherein it further comprises at least one stack of antenna-effect materials according to claim 1.

12. The optoelectronic device comprising at least one light emitter, wherein it further comprises at least one stack of antenna-effect materials according to claim 1, wherein it comprises a plurality of pixels which each comprise a plurality of sub-pixels, each sub-pixel is configured to emit a specific color and comprises the at least one light emitter emitting a light radiation of a given color, at least one of the sub-pixels comprises:
at least one light conversion module disposed on the at least one light emitter that the at least one sub-pixel comprises, the light conversion module comprising at least one conversion pad capable of emitting a radiation of a color different from that of the light radiation emitted by the at least one light emitter,
and/or
at least one filter disposed on said light conversion module and which is capable of emitting a radiation of the same color as that of the light radiation emitted by the light conversion module and/or capable of blocking any radiation of a color different from that of the light radiation emitted by the light conversion module or, when the at least one sub-pixel is devoid of the light conversion module, the filter is disposed on the at least one light emitter that the at least one sub-pixel comprises and is capable of emitting a radiation of the same color as that of the light radiation emitted by the at least one light emitter and/or the filter is capable of blocking any radiation of a color different from that of the light radiation emitted by the at least one light emitter,
wherein the at least one conversion pad and/or the at least one filter comprises a stack of antenna-effect materials according to claim 1.

13. The optoelectronic device according to claim 11, wherein the stack is integrated within a photo- or heat-sensitive resin.

14. The optoelectronic device according to claim 11, wherein the at least one light emitter is a light-emitting diode (hereinafter abbreviated LED).

15. The optoelectronic device according to claim 11, wherein the optoelectronic device comprises a plurality of LEDs.

16. The optoelectronic device according to claim 11, wherein the at least one light emitter emits a light radiation with a wavelength comprised between 100 nm and 500 nm, and wherein the stack emits a light radiation with a wavelength comprised between 500 nm and 1000 nm.

17. The optoelectronic device according to claim 12, wherein the sub-pixels are controlled independently of each other by activating or modifying the electric current applied to the at least one light emitter which they include so as to modify the relative emission intensity of the sub-pixels.

18. The optoelectronic device comprising at least one light emitter, wherein it further comprises at least one stack of antenna-effect materials according to claim 1, wherein it comprises at least one pixel which comprises a 1st sub-pixel, a 2nd subpixel and a 3rd sub-pixel, each of the 1st, 2nd and 3rd sub-pixels comprises a light emitter which emits a light radiation of a given color and wherein:
on the light emitter of the 1st sub-pixel is disposed a 1st stack of antenna-effect materials,
on the light emitter of the 2nd sub-pixel is disposed a 2nd stack of antenna-effect materials,
on the light emitter of the 3rd sub-pixel is disposed a layer of a resin transparent to light radiation.

19. The optoelectronic device according to claim 18, wherein:
the light emitters of the 1st, 2nd and 3rd sub-pixels each emit a light radiation of blue color;
the at least one layer of rare earth of the 1st stack is capable of emitting a light radiation of red color;
the at least one layer of rare earth of the 2nd stack is capable of emitting a light radiation of green color.

20. The optoelectronic device according to claim 18, wherein the 1st stack and the 2nd stack are separated by a 1st light confinement wall and the 2nd stack and the layer of resin transparent to light radiation are separated by a 2nd light confinement wall.

21. The optoelectronic device according to claim 20, wherein the material of the 1st and 2nd light confinement walls is an absorbing or reflecting material.

22. A method for manufacturing a stack of antenna-effect materials according to claim 1, wherein it comprises at least the following steps:
the at least one layer of chromophore is carried out by molecular layer deposition (hereinafter abbreviated “MLD”) or by depositing a mixture comprising the chromophore and a photo-or heat-sensitive resin;
the at least one layer of rare earth is carried out by atomic layer deposition (hereinafter abbreviated “ALD”).

23. The method for manufacturing a stack according to claim 22, wherein the manufacturing method is carried out selectively on at least one determined light emitter of an optoelectronic device comprising at least one light emitter, wherein it further comprises at least one stack of antenna-effect materials, wherein the stack comprises at least one layer of rare earth on at least one layer of chromophore, the rare earth being different from lutetium and lanthanum and wherein it further comprises the following steps:
before the manufacture of the stack on the at least one determined light emitter, a protection of the light emitters on which the stack will not be carried out is performed, and
after the manufacture of said stack on the at least one determined light emitter, a deprotection of the light emitters on which the stack has not been carried out is performed.

24. The method for manufacturing a stack according to claim 23, wherein the protection of the light emitters on which the stack will not be carried out consists of the following steps:
a layer of SiN with a thickness comprised between 100 nm and 100 μm is deposited on all the light emitters, and this by a deposition technique chosen from ALD, chemical vapor deposition (known by the acronym “CVD”) or plasma-enhanced chemical vapor deposition (known by the acronym “PECVD”);
a layer of SiO₂ with a thickness comprised between 100 nm and 100 μm is deposited on the layer of SiN of all the light emitters by a deposition technique chosen from ALD, CVD or PECVD;
the layer of SiO₂ is removed by laser ablation from the at least one determined light emitter on which the stack will be carried out;
a self-assembled monolayer (hereinafter abbreviated “SAM”) of silane is deposited on the remaining layers of SiO₂, namely the layers of SiO₂ of the light emitters on which the stack will not be carried out, so as to protect the light emitters on which the stack will not be performed.

25. The method for manufacturing a stack according to claim 24, wherein the deprotection of the light emitters on which the stack has not been carried out is performed by removing by laser ablation the layer of SiO₂ and the SAM of silane which have been deposited on these light emitters or by removing only the SAM of silane by hydrolysis in an acidic or basic environment.

26. The method for manufacturing a stack according to claim 23, wherein the protection of the light emitters on which the stack will not be carried out consists in depositing on the light emitters a layer of a photo-or heat-sensitive resin.

27. The method for manufacturing a stack according to claim 26, wherein the deprotection of the light emitters on which the stack has not been carried out is performed by removing the layer of photo-or heat-sensitive resin using a plasma.
